(19) United States
(12) Patent Application Publication
(10) Pub. No.: US 2023/0299237 A1
(43) Pub. Date: Sep. 21, 2023

(54) ULTRAVIOLET (UV) LIGHT-EMITTING DIODE (LED) STRUCTURE AND MANUFACTURING METHOD THEREOF

(71) Applicant: ZHIXIN SEMICONDUCTOR (HANGZHOU) CO., LTD, Hangzhou, Zhejiang (CN)

(72) Inventor: Xiaohui HUANG, Hangzhou (CN)

(73) Assignee: ZHIXIN SEMICONDUCTOR (HANGZHOU) CO., LTD, Hangzhou, Zhejiang (CN)

(21) Appl. No.: 18/035,101

(22) PCT Filed: Oct. 21, 2021
(86) PCT No.: PCT/CN2021/125177

§ 371 Date: May 2, 2023

(30) Foreign Application Priority Data
Nov. 16, 2020 (CN) 2020112749990

(51) Int. Cl. H01L 33/32; H01L 33/20; H01L 33/06; H01L 33/14; H01L 33/40; H01L 33/00

(52) U.S. Cl. CPC H01L 33/32; H01L 33/0075; H01L 33/06; H01L 33/145; H01L 33/20; H01L 33/40; H01L 2933/0016

(57) ABSTRACT

The present disclosure provides an ultraviolet (UV) light-emitting diode (LED) and a manufacturing method thereof. The UV LED structure includes: a substrate, and an undoped AlN layer, an undoped AlGaN layer, an N-type doped AlGaN layer, an AlGaN quantum well structure, and an AlGaN electron barrier layer that are sequentially grown on one surface of the substrate; and P-type nanopillars vertically grown on the AlGaN electron barrier layer, where an N-electrode and a P-electrode are evaporated on the P-type nanopillar. In the UV LED structure according to the present disclosure, the diameter of the P-type nanopillar is controllable, and the density of the nanopillars is controllable. Metallic microbeads formed after annealing of a metal film are capable of guiding and catalyzing growth of nanopillars, such that the nanopillars grow vertically.

### CROSS REFERENCE TO RELATED APPLICATION

The present disclosure is a national stage application of International Patent Application No. PCT/CN2021/125177, filed on Oct. 21, 2021, which claims the priority to Chinese Patent Application 202011274999.0, titled “UV LED STRUCTURE AND MANUFACTURING METHOD THEREOF”, filed with China National Intellectual Property Administration (CNIPA) on Nov. 16, 2020, which is incorporated herein by reference in its entirety.

### TECHNICAL FIELD

The present disclosure relates to the technical field of semiconductor devices, and in particular to an ultraviolet (UV) light-emitting diode (LED) structure with P-type nanopillars and a manufacturing method thereof.

### BACKGROUND

Group III nitride UV materials (AlGaN) are the core materials of solid-state UV light sources. AlGaN UV LED products, as the mainstream products of UV light electronics at present, are capable of emitting UV light with a wavelength of 200 nm to 365 nm, and are widely used in fields such as polymer curing, sterilization, bio-detection, non-visible communication, and cold chain transportation.

Traditional UV lamps are mercury lamps, which have many application problems. For example, mercury is highly toxic and difficult to remove from the environment. In addition, the mercury lamp has a large size, which greatly restricts the application scenarios. Besides, the mercury lamp is fragile, which is also an obstacle to the expansion of application fields.

An LED light source has the advantages of small size, long service life and being non-toxic. The UV LED with UV-C radiation is the most important germicidal material for UV germicidal devices, and is widely used for surface, air and water sterilization due to its high speed and high efficiency in killing bacteria, and cells or viruses such as anthrax spores, E. coli, influenza and malaria. Meanwhile, UV-C belongs to a day-blind band, and has a short transmission distance. Therefore, UV-C is used for short-range strong anti-jamming communication in the military field.

In addition, the UV-B band has an excellent phototherapeutic effect, and is highly valued in optical therapy. Especially, the UV-B band has an excellent effect in vitiligo treatment.

A typical UV LED structure includes an N-type AlGaN layer, an AlGaN quantum well layer, an AlGaN electron barrier layer, a P-type AlGaN layer, and a P-type GaN layer. Since the P-type AlGaN material with a high Al content has high hole activation energy, the P-type AlGaN has low hole concentration. Therefore, in the actual structure design process, P-type GaN is introduced to serve as the P-type layer material, which not only improves the hole concentration, but also ensures that the contact resistance is not excessively high. However, the energy gap of an AlGaN quantum well is relatively large, where the energy gap at 280 nm is 4.4 eV, and the energy gap of GaN as a P-type layer is 3.4 eV. Therefore, UV light emitted from the quantum well is easily absorbed by the P-type layer, which greatly reduces the light extraction efficiency of the UV light. The absorption spectrum test shows that GaN with a thickness of only 20 nm can absorb more than 80% of UV light at 280 nm. The severe absorption of UV light by the P-type layer leads to low light extraction efficiency of the UV LED, and the extraction efficiency is less than 10%. In general, a 20 mil×20 mil UV AlGaN LED chip only has luminous brightness of about 2 mW with a drive current of 20 mA, which leads to low efficiency of sterilization, phototherapy and curing, thus greatly limiting the market application.

### SUMMARY

The technical problem to be solved/the objective to be achieved by the present disclosure at least includes: providing a UV LED structure and a manufacturing method thereof.

In order to achieve the above objectives, the present disclosure discloses the following technical solutions:

The present disclosure provides a UV LED structure, including: a substrate, and an undoped AlN layer, an undoped AlGaN layer, an N-type doped AlGaN layer, an AlGaN quantum well structure, and an AlGaN electron barrier layer that are sequentially grown on one surface of the substrate; and

P-type nanopillars that are vertically grown on the AlGaN electron barrier layer;

where an N-electrode and a P-electrode are evaporated on the P-type nanopillar.

According to an aspect of the present disclosure, the P-type nanopillar is a P-type AlGaN nanopillar or a P-type GaN nanopillar.

According to an aspect of the present disclosure, the undoped AlN layer and the undoped AlGaN layer each have a thickness of 10 to 5000 nm; an Al content in the undoped AlGaN layer is 15% to 95%; and

the N-type doped AlGaN layer has a thickness of 10 to 5000 nm; and an Al content in the N-type doped AlGaN layer is 15% to 95%.

According to an aspect of the present disclosure, the AlGaN quantum well structure is obtained by alternately growing AlGaN quantum well layers and AlGaN quantum barriers; and the number of the grown AlGaN quantum well layers is the same as that of the grown AlGaN quantum barriers, which is 2 to 20.

According to an aspect of the present disclosure, an Al content in the AlGaN quantum well layer and an Al content in the AlGaN quantum barrier are 15% to 85%; and

the AlGaN quantum well layer has a thickness of 1 to 10 nm, and the AlGaN quantum barrier has a thickness of 1 to 20 nm.

According to an aspect of the present disclosure, the AlGaN electron barrier layer is obtained by alternately growing AlGaN with same or different Al contents; the AlGaN electron barrier layer has a thickness of 10 to 200 nm, and the Al content in the AlGaN electron barrier layer is 15% to 95%.

According to an aspect of the present disclosure, the P-type nanopillar has a diameter of 10 nm to 1000 nm.

According to an aspect of the present disclosure, the N-electrode and the P-electrode are made of metal Au, Ag, Sn, Cu, Cr, Mn, Ni or Ti; or

the N-electrode and the P-electrode is made of a compound of Au, a compound of Ag, a compound of Sn, a compound of Cu, a compound of Cr, a compound of Mn, a compound of Ni, or a compound of Ti.

To achieve the foregoing objective, the present disclosure further provides a method for manufacturing the UV LED structure, including
placing a substrate in a growth reaction chamber, and sequentially growing an undoped AlN layer, an undoped AlGaN layer, and an N-type doped AlGaN layer on one surface of the substrate;
sequentially growing an AlGaN quantum well structure and an AlGaN electron barrier layer on the N-type AlGaN layer;
vertically growing P-type nanopillars on the AlGaN electron barrier layer; and
evaporating an N-electrode and a P-electrode on the P-type nanopillar.

According to an aspect of the present disclosure, after the vertically growing P-type nanopillars on the AlGaN electron barrier layer, the method further includes: filling space between the P-type nanopillars with an insulating layer, and then removing the insulating layer after the N-electrodes and the P-electrodes are evaporated on the P-type nanopillars.

According to an aspect of the present disclosure, the growing P-type nanopillars includes:
separately injecting a main-group III metal source to a growth reaction chamber, to form a metal film on a surface of the substrate;
annealing the metal film to form metallic microbeads; and
forming nanopillars at the metallic microbeads, and then performing P-type doping to form the P-type nanopillars.

In the UV LED structure according to the present disclosure, the diameter of the P-type nanopillar is controllable, and the density of the nanopillars is controllable. Metallic microbeads formed after annealing of a metal film are capable of guiding and catalyzing growth of nanopillars, such that the nanopillars grow vertically. Moreover, in the growth process, it is unnecessary to take out the substrate from the reaction chamber, and an in-situ growth method is used. UV light generated from the AlGaN quantum well can be effectively extracted without being absorbed, thereby greatly improving the optical power of the UV LED.

### BRIEF DESCRIPTION OF THE DRAWINGS

FIG. 1 is a schematic diagram of a UV LED structure according to the present disclosure, where meanings of reference numerals are as follows: 601: substrate, 602: undoped AlN layer and undoped AlGaN layer, 603: N-type doped AlGaN layer, 604: AlGaN quantum well structure, 605: AlGaN electron barrier layer, 606: N-electrode, and 607: P-electrode;

FIG. 2 is a flowchart of a manufacturing method of the UV LED structure according to the present disclosure;

FIG. 3 is a schematic structural diagram after a metal film is formed on a surface of the AlGaN electron barrier layer, where meanings of reference numerals are as follows: 101: substrate, 102: undoped AlN and AlGaN layer, 103: N-type AlGaN layer, 104: AlGaN quantum well structure layer, 105: AlGaN electron barrier layer, and 106: metal film;

FIG. 4 is a schematic structural diagram after metallic microbeads are formed by annealing the metal film, where meanings of reference numerals are as follows: 201: substrate, 202: undoped AlN and AlGaN layer, 203: N-type AlGaN layer, 204: AlGaN quantum well structure layer, 205: AlGaN electron barrier layer, and 206: metallic microbeads;

FIG. 5 is a schematic structural diagram after P-type nanopillars are obtained by P-type doping, where meanings of reference numerals are as follows: 301: substrate, 302: undoped AlN and AlGaN layer, 303: N-type AlGaN layer, 304: AlGaN quantum well structure layer, 305: AlGaN electron barrier layer, and 306: P-type nanopillar;

FIG. 6 is a schematic structural diagram of filling space between the P-type nanopillars with an insulating layer, where meanings of reference numerals are as follows: 401: substrate, 402: undoped AlN and AlGaN layer, 403: N-type AlGaN layer, 404: AlGaN quantum well structure layer, 405: AlGaN electron barrier layer, and 406: insulating filler layer; and

FIG. 7 is a schematic structural diagram after evaporation of N-type and P-type electrodes, where meanings of reference numerals are as follows: 501: substrate, 502: undoped AlN and AlGaN layer, 503: N-type AlGaN layer, 504: AlGaN quantum well layer, 505: AlGaN electron barrier layer, 506: insulating filler layer, 507: N-electrode, and 508: P-electrode.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts should fall within the protection scope of the present disclosure.

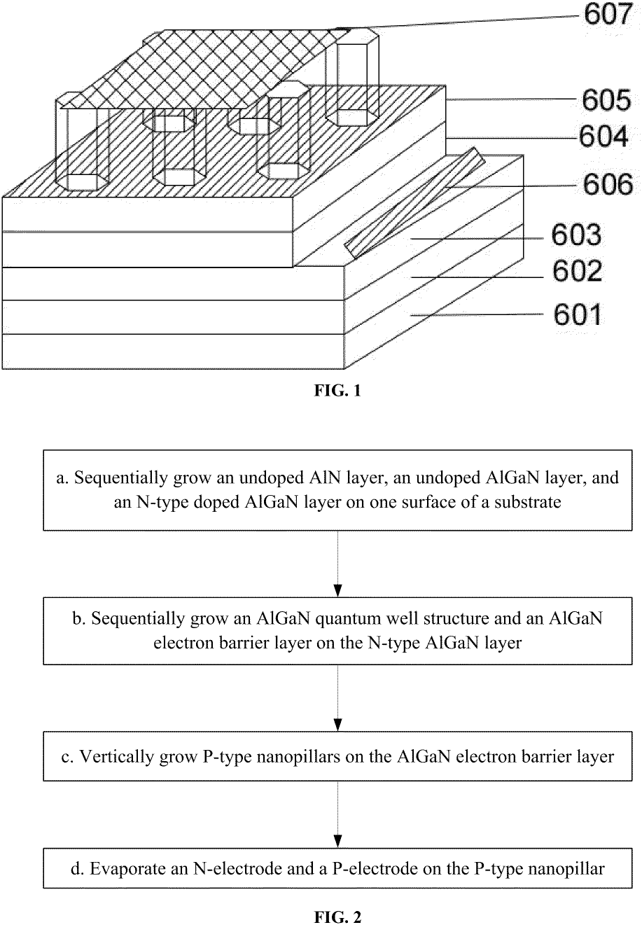

FIG. 1 is a UV LED structure according to the present disclosure. As shown in FIG. 1, the UV LED structure includes:
a substrate 601, and an undoped AlN layer and undoped AlGaN layer 602, an N-type doped AlGaN layer 603, an AlGaN quantum well structure 604, and an AlGaN electron barrier layer 605 that are sequentially grown on one surface of the substrate; and
P-type nanopillars that are vertically grown on the AlGaN electron barrier layer 605;
where an N-electrode 606 and a P-electrode 607 are evaporated on the P-type nanopillar.

According to an implementation of the present disclosure, the P-type nanopillar is a P-type AlGaN nanopillar or a P-type GaN nanopillar.

According to an implementation of the present disclosure, space between the P-type nanopillars further needs to be filled with an insulating layer, and then the insulating layer is removed after the N-electrodes and the P-electrodes are evaporated on the P-type nanopillars.

In the present disclosure, the substrate is preferably made of sapphire, silicon, silicon carbide or graphene.

A growth reaction chamber is used to grow structures of each layer and the P-type nanopillars. The growth reaction chamber is preferably one of a metal-organic chemical vapor deposition (MOCVD) device, a molecular beam epitaxy (MBE) device, and a hydride vapor phase epitaxy (HVPE) device.

Preferably, the undoped AlN layer and the undoped AlGaN layer each have a thickness of 10 to 5000 nm; an Al content in the undoped AlGaN layer is 15% to 95%; the N-type doped AlGaN layer has a thickness of 10 to 5000 nm; and an Al content in the N-type doped AlGaN layer is 15% to 95%.

Preferably, the AlGaN quantum well structure is obtained by alternately growing AlGaN quantum well layers and AlGaN quantum barriers; and the number of the grown AlGaN quantum well layers is the same as that of the grown AlGaN quantum barriers, which is 2 to 20.

Further, an Al content in the AlGaN quantum well layer and an Al content in the AlGaN quantum barrier are 15% to 85%; the AlGaN quantum well layer has a thickness of 1 to 10 nm, and the AlGaN quantum barrier has a thickness of 1 to 20 nm.

Preferably, the AlGaN electron barrier layer is obtained by alternately growing AlGaN with same or different Al contents; the AlGaN electron barrier layer has a thickness of 10 to 200 nm, and the Al content in the AlGaN electron barrier layer is 15% to 95%.

In the present disclosure, the process of growing the P-type AlGaN nanopillars or P-type GaN nanopillars includes the following steps:
separately injecting a main-group III metal source to a growth reaction chamber, to form a metal film on a surface of the substrate;
annealing the metal film to form metallic microbeads; and
forming nanopillars at the metallic microbeads, and then performing P-type doping to form the P-type nanopillars.

FIG. 2 is a flowchart of a manufacturing method of the UV LED structure according to the present disclosure. As shown in FIG. 2, the method for manufacturing the UV LED according to the present disclosure includes the following steps:

a. Place a substrate in a growth reaction chamber, and sequentially grow an undoped AlN layer, an undoped AlGaN layer, and an N-type doped AlGaN layer on one surface of the substrate.

b. Sequentially grow an AlGaN quantum well structure and an AlGaN electron barrier layer on the N-type AlGaN layer.

c. Vertically grow P-type nanopillars on the AlGaN electron barrier layer.

d. Evaporate an N-electrode and a P-electrode on the P-type nanopillar.

According to an implementation of the present disclosure, after step c, pace between the P-type nanopillars further needs to be filled with an insulating layer, and then the insulating layer is removed after the N-electrodes and the P-electrodes are evaporated on the P-type nanopillars.

In the present disclosure, the substrate is preferably made of sapphire, silicon, silicon carbide or graphene.

A growth reaction chamber is used to grow structures of each layer and the P-type nanopillars. The growth reaction chamber is preferably one of a MOCVD device, a MBE device, and a HVPE device.

Preferably, the undoped AlN layer and the undoped AlGaN layer each have a thickness of 10 to 5000 nm; an Al content in the undoped AlGaN layer is 15% to 95%; the N-type doped AlGaN layer has a thickness of 10 to 5000 nm; and an Al content in the N-type doped AlGaN layer is 15% to 95%.

Preferably, the AlGaN quantum well structure is obtained by alternately growing AlGaN quantum well layers and AlGaN quantum barriers; and the number of the grown AlGaN quantum well layers is the same as that of the grown AlGaN quantum barriers, which is 2 to 20.

Further, an Al content in the AlGaN quantum well layer and an Al content in the AlGaN quantum barrier are 15% to 85%; the AlGaN quantum well layer has a thickness of 1 to 10 nm, and the AlGaN quantum barrier has a thickness of 1 to 20 nm.

Preferably, the AlGaN electron barrier layer is obtained by alternately growing AlGaN with same or different Al contents; the AlGaN electron barrier layer has a thickness of 10 to 200 nm, and the Al content in the AlGaN electron barrier layer is 15% to 95%.

In step c, the process of growing the P-type AlGaN nanopillars or P-type GaN nanopillars includes the following steps:
separately injecting a main-group III metal source to a growth reaction chamber, to form a metal film on a surface of the substrate;
annealing the metal film to form metallic microbeads; and
forming nanopillars at the metallic microbeads, and then performing P-type doping to form the P-type nanopillars.

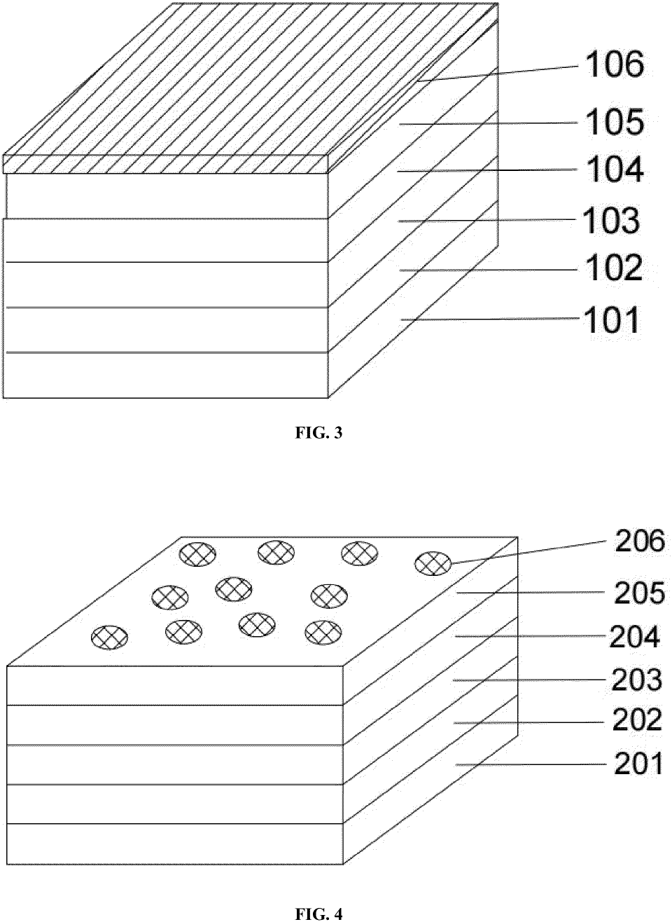

Further, FIG. 3 to FIG. 7 are schematic diagrams of structure growth before the UV LED structure in FIG. 1 is formed.

The process of forming the P-type AlGaN nanopillars or P-type GaN nanopillars is as shown in FIG. 3 to FIG. 5. FIG. 3 is a schematic structural diagram after a metal film is formed on a surface of the AlGaN electron barrier layer. In FIG. 3, 101 denotes a substrate, 102 denotes an undoped AlN and AlGaN layer, 103 denotes an N-type AlGaN layer, 104 denotes an AlGaN quantum well structure layer, 105 denotes an AlGaN electron barrier layer, and 106 denotes a metal film.

FIG. 4 is a schematic structural diagram after metallic microbeads are formed by annealing the metal film. In FIG. 4, 201 denotes a substrate, 202 denotes an undoped AlN and AlGaN layer, 203 denotes an N-type AlGaN layer, 204 denotes an AlGaN quantum well structure layer, 205 denotes an AlGaN electron barrier layer, and 206 denotes metallic microbeads.

FIG. 5 is a schematic structural diagram after P-type nanopillars are obtained by P-type doping. In FIG. 5, 301 denotes a substrate, 302 denotes an undoped AlN and AlGaN layer, 303 denotes an N-type AlGaN layer, 304 denotes an AlGaN quantum well structure layer, 305 denotes an AlGaN electron barrier layer, and 306 denotes a P-type nanopillar.

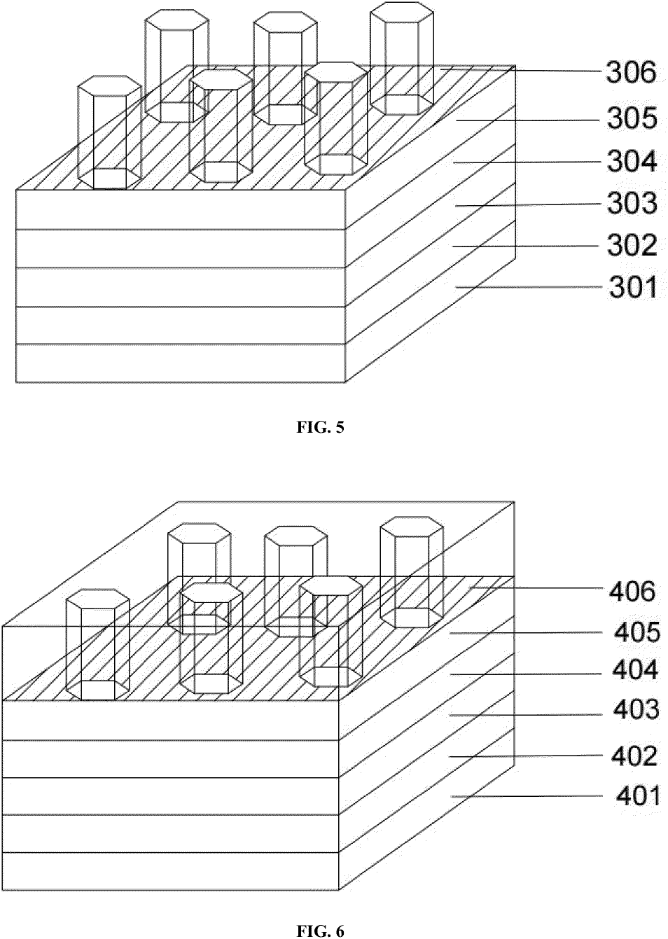

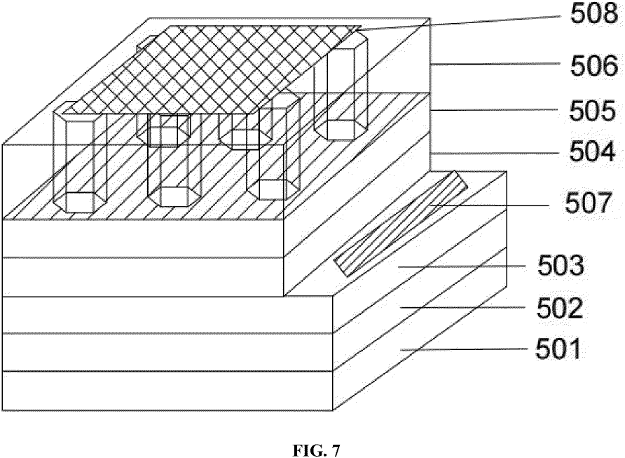

Further, the process of filling space between the P-type nanopillars with an insulating layer, and then removing the insulating layer after the N-electrodes and the P-electrodes are evaporated on the P-type nanopillars is as shown in FIG. 6, FIG. 7, and FIG. 1. FIG. 6 is a schematic structural diagram of filling space between the P-type nanopillars with an insulating layer. In FIG. 6, 401 denotes a substrate, 402 denotes an undoped AlN and AlGaN layer, 403 denotes an N-type AlGaN layer, 404 denotes an AlGaN quantum well structure layer, 405 denotes an AlGaN electron barrier layer, and 406 denotes an insulating filler layer.

FIG. 7 is a schematic structural diagram after evaporation of N-type and P-type electrodes. In FIG. 7, 501 denotes a substrate, 502 denotes an undoped AlN and AlGaN layer, 503 denotes an N-type AlGaN layer, 504 denotes an AlGaN quantum well layer, 505 denotes an AlGaN electron barrier layer, 506 denotes an insulating filler layer, 507 denotes an N-electrode, and 508 denotes a P-electrode.

The schematic diagram of the UV LED structure in FIG. 1 does not includes the insulating layer.

Further, the P-type nanopillar has a diameter of 10 nm to 1000 nm.

The N-electrode and the P-electrode are made of metal Au, Ag, Sn, Cu, Cr, Mn, Ni or Ti; or the N-electrode and the P-electrode is made of a compound of Au, a compound of Ag, a compound of Sn, a compound of Cu, a compound of Cr, a compound of Mn, a compound of Ni, or a compound of Ti.

According to the foregoing solution of the present disclosure, the diameter of the P-type nanopillar is controllable, and the density of the nanopillars is controllable. Metallic microbeads formed after annealing of a metal film are capable of guiding and catalyzing growth of nanopillars, such that the nanopillars grow vertically. Moreover, in the growth process, it is unnecessary to take out the substrate from the reaction chamber, and an in-situ growth method is used. UV light generated from the AlGaN quantum well can be effectively extracted without being absorbed, thereby greatly improving the optical power of the UV LED.

According to the above solution of the present disclosure, some specific embodiments are provided as follows:

### Embodiment 1

1. A temperature of a metal-organic chemical vapor deposition (MOCVD) reaction chamber was increased to 1250° C., a pressure was adjusted to 100 mbar, and a rotational speed was 1000 rpm. Hydrogen, trimethylaluminum, and ammonia were injected for 90 min, to form an undoped AlN layer with a thickness of 1500 nm.

2. The temperature was reduced to 1150° C., the pressure was adjusted to 200 mbar, and the rotational speed was 1000 rpm. Hydrogen, trimethyl gallium, trimethylaluminum, and ammonia were injected for 60 min. An undoped AlGaN layer with a thickness of 1000 nm was grown, where an Al content of AlGaN was 56%.

3. With the temperature and pressure unchanged, hydrogen, trimethyl gallium, trimethylaluminum, and ammonia were injected for 90 min, and silane was doped. An N-type AlGaN layer with a thickness of 1500 nm was grown, where an Al content of AlGaN was 56%, and a doping concentration of N-type AlGaN was 1×10¹⁹ cm⁻³.

4. The temperature was maintained at 1150° C., the pressure was adjusted to 200 mbar, and a rotational speed was 1000 rpm. Hydrogen, trimethyl gallium, trimethylaluminum, and ammonia were injected, to grow an AlGaN quantum barrier, where AlGaN had an Al content of 56%, and was doped with impurity Si having a doping concentration of 5×10¹⁷ cm⁻³ and a thickness of 12 nm.

5. The temperature was maintained at 1150° C., the pressure was adjusted to 200 mbar, and the rotational speed was 1000 rpm. Hydrogen, trimethyl gallium, trimethylaluminum, and ammonia were injected, to grow an AlGaN quantum well, where AlGaN had an Al content of 30% and a thickness of 3 nm.

6. Step 4 to step 5 were cycled 6 times.

7. The temperature was maintained at 1150° C., the pressure was adjusted to 200 mbar, and the rotational speed was 1000 rpm. Hydrogen, trimethyl gallium, trimethylaluminum, and ammonia were injected to grow an AlGaN quantum barrier, where AlGaN had an Al content of 56%, and was doped with impurity Mg at a doping concentration of 1×10¹⁸ cm⁻³. The last quantum barrier was grown with a growth time of 1 min and a thickness of 12 nm.

8. The temperature was maintained at 1150° C., the pressure was adjusted to 200 mbar, and the rotational speed was 1000 rpm. Hydrogen, trimethyl gallium, trimethylaluminum, and ammonia were injected, to grow the first AlGaN electron barrier layer, where an Al content of AlGaN was 65%. Impurity Mg was doped, where a doping concentration was 1×10¹⁹ cm⁻³, and a thickness was 10 nm.

9. The temperature was maintained at 1150° C., the pressure was adjusted to 200 mbar, and a rotational speed was 1000 rpm. Hydrogen, trimethyl gallium, trimethylaluminum, and ammonia were injected, to grow the second AlGaN electron barrier layer, where an Al content of AlGaN was 45%. Impurity Mg was doped, where a doping concentration was 1×10¹⁹ cm⁻³, and a thickness was 8 nm.

10. The following step 11 to step 12 were repeated 5 times, to form 5 periods of high-barrier AlGaN electron barrier layers and low-barrier AlGaN electron barrier layers.

11. The temperature was reduced to 980° C., the pressure was adjusted to 400 mbar, and the rotational speed was 1000 rpm. Trimethyl gallium and hydrogen where injected, while injection of ammonia was stopped, to form a gallium film with a thickness of 5 nm.

12. The temperature was maintained at 980° C., the pressure was maintained at 400 mbar, and the rotational speed was adjusted to 500 rpm. Injection of trimethyl gallium was stopped, and after a rest of 5 min, the gallium film was condensed into gallium pellets.

13. The temperature was maintained at 980° C., the pressure was maintained at 400 mbar, and the rotational speed was adjusted to 500 rpm. Hydrogen, ammonia, and trimethyl gallium were injected. In this case, GaN grew vertically along the gallium pellets, to form GaN nanopillars. The nanopillar had a diameter of 100 nm, and a distance between the nanopillars was about 200 nm. The GaN nanopillar was grown to reach a height of 200 nm under this condition, and was doped with Mg at a doping concentration of 1×10¹⁹ cm⁻³ during growth.

14. After the foregoing steps were completed, the substrate was placed into a PECVD device to be evaporated with SiO₂, so as to fill up space between the GaN nanopillars.

15. N-electrodes and P-electrodes were manufactured on this basis, where the N-electrodes and the P-electrodes were made of Ti/Al/Ti/Au. The substrate was made into chips with a size of 1 mm², and then the filled SiO₂ was etched off with a BOE solution, to complete manufacturing of the UV LED.

Experiment effect: with a current of 350 mA, the wavelength was 280 nm, the brightness was 180 mW, and the forward voltage was 6.0 V.

### Embodiment 2

1. A temperature of a MOCVD reaction chamber was increased to 1280° C., a pressure was adjusted to 100 mbar, and a rotational speed was 1200 rpm. Hydrogen, trimethylaluminum, and ammonia were injected for 120 min, to form an undoped AlN layer with a thickness of 2000 nm.

2. The temperature was reduced to 1110° C., the pressure was adjusted to 200 mbar, and the rotational speed was 1200 rpm. Hydrogen, trimethyl gallium, trimethylaluminum, and ammonia were injected for 120 min. An undoped AlGaN layer with a thickness of 2000 nm was grown, where an Al content of AlGaN was 58%.

3. With the temperature and pressure unchanged, hydrogen, trimethyl gallium, trimethylaluminum, and ammonia were injected for 90 min, and silane was doped. An N-type AlGaN layer with a thickness of 1500 nm was grown, where an Al content of AlGaN was 58%, and a doping concentration of N-type AlGaN was 1×10¹⁹ cm⁻³.

4. The temperature was maintained at 1110° C., the pressure was adjusted to 200 mbar, and a rotational speed was 1200 rpm. Hydrogen, trimethyl gallium, trimethylaluminum, and ammonia were injected, to grow an AlGaN quantum barrier, where AlGaN had an Al content of 58%, and was doped with impurity Si having a doping concentration of 1×10¹⁷ cm⁻³ and a thickness of 15 nm.

5. The temperature was maintained at 1110° C., the pressure was adjusted to 200 mbar, and the rotational speed was 1200 rpm. Hydrogen, trimethyl gallium, trimethylaluminum, and ammonia were injected, to grow an AlGaN quantum well, where AlGaN had an Al content of 30% and a thickness of 2.5 nm.

6. Step 4 to step 5 were cycled 8 times.

7. The temperature was maintained at 1110° C., the pressure was adjusted to 200 mbar, and the rotational speed was 1200 rpm. Hydrogen, trimethyl gallium, trimethylaluminum, and ammonia were injected to grow an AlGaN quantum barrier, where AlGaN had an Al content of 58%, and was doped with impurity Mg at a doping concentration of 1×10¹⁸ cm⁻³. The last quantum barrier was grown with a growth time of 1 min and a thickness of 15 nm.

8. The temperature was maintained at 1110° C., the pressure was adjusted to 200 mbar, and the rotational speed was 1200 rpm. Hydrogen, trimethyl gallium, trimethylaluminum, and ammonia were injected, to grow the first AlGaN electron barrier layer, where an Al content of AlGaN was 68%. Impurity Mg was doped, where a doping concentration was 1×10¹⁹ cm⁻³, and a thickness was 40 nm.

9. The temperature was reduced to 950° C., the pressure was adjusted to 400 mbar, and the rotational speed was 500 rpm. Trimethyl gallium and hydrogen where injected, while injection of ammonia was stopped, to form a gallium film with a thickness of 20 nm.

10. The temperature was maintained at 950° C., the pressure was maintained at 400 mbar, and the rotational speed was adjusted to 500 rpm. Injection of trimethyl gallium was stopped, and after a rest of 10 min, the gallium film was condensed into gallium pellets.

11. The temperature was maintained at 950° C., the pressure was maintained at 400 mbar, and the rotational speed was adjusted to 500 rpm. Hydrogen, ammonia, and trimethyl gallium were injected. In this case, GaN grew vertically along the gallium pellets, to form GaN nanopillars. The nanopillar had a diameter of 500 nm, and a distance between the nanopillars was about 500 nm. The GaN nanopillar was grown to reach a height of 300 nm under this condition, and was doped with Mg at a doping concentration of 2×10¹⁹ cm⁻³ during growth.

12. After the foregoing steps were completed, the substrate was placed into a PECVD device to be evaporated with SiO₂, so as to fill up space between the GaN nanopillars.

13. N-electrodes and P-electrodes were manufactured on this basis, where the N-electrodes and the P-electrodes were made of Ti/Al/Ti/Au. The substrate was made into chips with a size of 1 mm², and then the filled SiO₂ was etched off with a BOE solution, to complete manufacturing of the UV LED.

Experiment effect: with a current of 350 mA, the wavelength was 280 nm, the brightness was 150 mW, and the forward voltage was 5.5 V.

### Embodiment 3

1. A temperature of a MOCVD reaction chamber was increased to 1250° C., a pressure was adjusted to 50 mbar, and a rotational speed was 1200 rpm. Hydrogen, trimethylaluminum, and ammonia were injected for 120 min, to form an undoped AlN layer with a thickness of 2000 nm.

2. The temperature was reduced to 1150° C., the pressure was adjusted to 100 mbar, and the rotational speed was 1200 rpm. Hydrogen, trimethyl gallium, trimethylaluminum, and ammonia were injected for 90 min. An undoped AlGaN layer with a thickness of 1500 nm was grown, where an Al content of AlGaN was 60%.

3. With the temperature and pressure unchanged, hydrogen, trimethyl gallium, trimethylaluminum, and ammonia were injected for 120 min, and silane was doped. An N-type AlGaN layer with a thickness of 2000 nm was grown, where an Al content of AlGaN was 60%, and a doping concentration of N-type AlGaN was 1×10¹⁹ cm⁻³.

4. The temperature was maintained at 1150° C., the pressure was adjusted to otational speed was 1200 rpm. Hydrogen, trimethyl gallium, trimethylaluminum, and ammonia were injected, to grow an AlGaN quantum barrier, where AlGaN had an Al content of 60%, and was doped with impurity Si having a doping concentration of 3×10¹⁷ cm⁻³ and a thickness of 20 nm.

5. The temperature was maintained at 1150° C., the pressure was adjusted to 100 mbar, and the rotational speed was 1200 rpm. Hydrogen, trimethyl gallium, trimethylaluminum, and ammonia were injected, to grow an AlGaN quantum well, where AlGaN had an Al content of 30% and a thickness of 2.5 nm.

6. Step 4 to step 5 were cycled 10 times.

7. The temperature was maintained at 1150° C., the pressure was adjusted to 200 mbar, and a rotational speed was 1200 rpm. Hydrogen, trimethyl gallium, trimethylaluminum, and ammonia was injected, to grow an AlGaN quantum barrier, where AlGaN had an Al content of 58%, and was doped with impurity Mg having a doping concentration of 1×10¹⁸ cm⁻³ and a thickness of 20 nm, to grow the last quantum barrier.

8. The temperature was maintained at 1150° C., the pressure was adjusted to 200 mbar, and the rotational speed was 1200 rpm. Hydrogen, trimethyl gallium, trimethylaluminum, and ammonia were injected, to grow the first AlGaN electron barrier layer, where an Al content of AlGaN was 80%. Impurity Mg was doped, where a doping concentration was 1×10¹⁹ cm⁻³, and a thickness was 40 nm.

9. The temperature was reduced to 950° C., the pressure was adjusted to 500 mbar, and the rotational speed was 500 rpm. Trimethyl gallium and hydrogen where injected, while injection of ammonia was stopped, to form a gallium film with a thickness of 30 nm.

10. The temperature was maintained at 950° C., the pressure was maintained at 500 mbar, and the rotational speed was adjusted to 500 rpm. Injection of trimethyl gallium was stopped, and after a rest of 10 min, the gallium film was condensed into gallium pellets.

11. The temperature was maintained at 950° C., the pressure was maintained at 500 mbar, and the rotational speed was adjusted to 500 rpm. Hydrogen, ammonia, and trimethyl gallium were injected. In this case, GaN grew vertically along the gallium pellets, to form GaN nanopillars. The nanopillar had a diameter of 750 nm, and a distance between the nanopillars was about 500 nm. The GaN nanopillar was grown to reach a height of 300 nm under this condition, and was doped with Mg at a doping concentration of 1×10¹⁹ cm⁻³ during growth.

12. After the foregoing steps were completed, the substrate was placed into a PECVD device to be evaporated with SiO₂, so as to fill up space between the GaN nanopillars.

13. N-electrodes and P-electrodes were manufactured on this basis, where the N-electrodes and the P-electrodes were made of Ti/Al/Ti/Au. The substrate was made into chips with a size of 1 mm², and then the filled SiO₂ was etched off with a BOE solution, to complete manufacturing of the UV LED.

Experiment effect: with a current of 350 mA, the wavelength was 280 nm, the brightness was 160 mW, and the forward voltage was 5.5 V.

### Embodiment 4

1. A temperature of a MOCVD reaction chamber was increased to 1250° C., a pressure was adjusted to 50 mbar, and a rotational speed was 1000 rpm. Hydrogen, trimethylaluminum, and ammonia were injected for 90 min, to form an undoped AlN layer with a thickness of 1500 nm.

2. The temperature was reduced to 1150° C., the pressure was adjusted to 100 mbar, and the rotational speed was 1000 rpm. Hydrogen, trimethyl gallium, trimethylaluminum, and ammonia were injected for 60 min. An undoped AlGaN layer with a thickness of 1000 nm was grown, where an Al content of AlGaN was 50%.

3. With the temperature and pressure unchanged, hydrogen, trimethyl gallium, trimethylaluminum, and ammonia were injected for 90 min, and silane was doped. An N-type AlGaN layer with a thickness of 1500 nm was grown, where an Al content of AlGaN was 50%, and a doping concentration of N-type AlGaN was 1×10¹⁹ cm⁻³.

4. The temperature was maintained at 1150° C., the pressure was adjusted to 100 mbar, and a rotational speed was 1000 rpm. Hydrogen, trimethyl gallium, trimethylaluminum, and ammonia was injected, to grow an AlGaN quantum barrier, where AlGaN had an Al content of 50%, and was doped with impurity Si having a doping concentration of 2×10¹⁷ cm⁻³ and a thickness of 15 nm.

5. The temperature was maintained at 1150° C., the pressure was adjusted to 100 mbar, and the rotational speed was 1000 rpm. Hydrogen, trimethyl gallium, trimethylaluminum, and ammonia were injected, to grow an AlGaN quantum well, where AlGaN had an Al content of 20% and a thickness of 3 nm.

6. Step 4 to step 5 were cycled 5 times.

7. The temperature was maintained at 1150° C., the pressure was adjusted to 100 mbar, and the rotational speed was 1000 rpm. Hydrogen, trimethyl gallium, trimethylaluminum, and ammonia were injected, to grow an AlGaN quantum barrier, where AlGaN had an Al content of 50% and a thickness of 15 nm, to grow the last quantum barrier.

8. The temperature was maintained at 1150° C., the pressure was adjusted to 100 mbar, and the rotational speed was 1000 rpm. Hydrogen, trimethyl gallium, trimethylaluminum, and ammonia were injected, to grow the first AlGaN electron barrier layer, where an Al content of AlGaN was 55%. Impurity Mg was doped, where a doping concentration was 1×10¹⁹ cm⁻³, and a thickness was 10 nm.

9. The temperature was maintained at 1150° C., the pressure was adjusted to 100 mbar, and a rotational speed was 1000 rpm. Hydrogen, trimethyl gallium, trimethylaluminum, and ammonia were injected, to grow the second AlGaN electron barrier layer, where an Al content of AlGaN was 45%. Impurity Mg was doped, where a doping concentration was 1×10¹⁹ cm⁻³, and a thickness was 8 nm.

10. The following step 11 to step 12 were repeated 8 times, to form 8 periods of high-barrier AlGaN electron barrier layers and low-barrier AlGaN electron barrier layers.

11. The temperature was reduced to 980° C., the pressure was adjusted to 400 mbar, and the rotational speed was 1000 rpm. Trimethyl gallium and hydrogen where injected, while injection of ammonia was stopped, to form a gallium film with a thickness of 40 nm.

12. The temperature was maintained at 980° C., the pressure was maintained at 400 mbar, and the rotational speed was adjusted to 500 rpm. Injection of trimethyl gallium was stopped, and after a rest of 10 min, the gallium film was condensed into gallium pellets.

13. The temperature was maintained at 980° C., the pressure was maintained at 400 mbar, and the rotational speed was adjusted to 500 rpm. Hydrogen, ammonia, and trimethyl gallium were injected. In this case, GaN grew vertically along the gallium pellets, to form GaN nanopillars. The nanopillar had a diameter of 1000 nm, and a distance between the nanopillars was about 400 nm. The GaN nanopillar was grown to reach a height of 200 nm under this condition, and was doped with Mg at a doping concentration of 1×10¹⁹ cm⁻³ during growth.

14. After the foregoing steps were completed, the substrate was placed into a PECVD device to be evaporated with SiO₂, so as to fill up space between the GaN nanopillars.

15. N-electrodes and P-electrodes were manufactured on this basis, where the N-electrodes and the P-electrodes were made of Ti/Al/Ti/Au. The substrate was made into chips with a size of 1 mm², and then the filled SiO₂ was etched off with a BOE solution, to complete manufacturing of the UV LED.

Experiment effect: with a current of 350 mA, the wavelength was 310 nm, the brightness was 150 mW, and the forward voltage was 6.0 V.

### Embodiment 5

1. A temperature of a MOCVD reaction chamber was increased to 1250° C., a pressure was adjusted to 50 mbar, and a rotational speed was 1000 rpm. Hydrogen, trimethylaluminum, and ammonia were injected for 60 min, to form an undoped AIN layer with a thickness of 1000 nm.

2. The temperature was reduced to 1150° C., the pressure was adjusted to 100 mbar, and the rotational speed was 1000 rpm. Hydrogen, trimethyl gallium, trimethylaluminum, and ammonia were injected for 120 min. An undoped AlGaN layer with a thickness of 2000 nm was grown, where an Al content of AlGaN was 50%.

3. With the temperature and pressure unchanged, hydrogen, trimethyl gallium, trimethylaluminum, and ammonia were injected for 120 min, and silane was doped. An N-type AlGaN layer with a thickness of 2000 nm was grown, where an Al content of AlGaN was 50%, and a doping concentration of N-type AlGaN was 5×10¹⁸ cm⁻³.

4. The temperature was maintained at 1150° C., the pressure was adjusted to 100 mbar, and a rotational speed was 1000 rpm. Hydrogen, trimethyl gallium, trimethylaluminum, and ammonia were injected, to grow an AlGaN quantum barrier, where AlGaN had an Al content of 50%, and was doped with impurity Si having a doping concentration of 2×10¹⁷ cm⁻³ and a thickness of 12 nm.

5. The temperature was maintained at 1150° C., the pressure was adjusted to 100 mbar, and the rotational speed was 1000 rpm. Hydrogen, trimethyl gallium, trimethylaluminum, and ammonia were injected, to grow an AlGaN quantum well, where AlGaN had an Al content of 18% and a thickness of 2.5 nm.

6. Step 4 to step 5 were cycled 8 times.

7. The temperature was maintained at 1150° C., the pressure was adjusted to 100 mbar, and the rotational speed was 1000 rpm. Hydrogen, trimethyl gallium, trimethylaluminum, and ammonia were injected, to grow an AlGaN quantum barrier, where AlGaN had an Al content of 50% and a thickness of 12 nm, to grow the last quantum barrier.

8. The temperature was maintained at 1150° C., the pressure was adjusted to 100 mbar, and the rotational speed was 1000 rpm. Hydrogen, trimethyl gallium, trimethylaluminum, and ammonia were injected, to grow the first AlGaN electron barrier layer, where an Al content of AlGaN was 60%. Impurity Mg was doped, where a doping concentration was 1×10¹⁹ cm⁻³, and a thickness was 15 nm.

9. The temperature was maintained at 1150° C., the pressure was adjusted to 100 mbar, and a rotational speed was 1000 rpm. Hydrogen, trimethyl gallium, trimethylaluminum, and ammonia were injected, to grow the second AlGaN electron barrier layer, where an Al content of AlGaN was 45%. Impurity Mg was doped, where a doping concentration was 1×10¹⁹ cm⁻³, and a thickness was 8 nm.

10. The following step 11 to step 12 were repeated 6 times, to form 6 periods of high-barrier AlGaN electron barrier layers and low-barrier AlGaN electron barrier layers.

11. The temperature was reduced to 900° C., the pressure was adjusted to 400 mbar, and the rotational speed was 600 rpm. Trimethyl gallium and hydrogen where injected, while injection of ammonia was stopped, to form a gallium film with a thickness of 20 nm.

12. The temperature was maintained at 900° C., the pressure was maintained at 400 mbar, and the rotational speed was adjusted to 600 rpm. Injection of trimethyl gallium was stopped, and after a rest of 20 min, the gallium film was condensed into gallium pellets.

13. The temperature was maintained at 900° C., the pressure was maintained at 400 mbar, and the rotational speed was adjusted to 600 rpm. Hydrogen, ammonia, and trimethyl gallium were injected. In this case, GaN grew vertically along the gallium pellets, to form GaN nanopillars. The nanopillar had a diameter of 500 nm, and a distance between the nanopillars was about 800 nm. The GaN nanopillar was grown to reach a height of 300 nm under this condition, and was doped with Mg at a doping concentration of 1×10¹⁹ cm⁻³ during growth.

14. After the foregoing steps were completed, the substrate was placed into a PECVD device to be evaporated with SiO₂, so as to fill up space between the GaN nanopillars.

15. N-electrodes and P-electrodes were manufactured on this basis, where the N-electrodes and the P-electrodes were made of Ti/Al/Ti/Au. The substrate was made into chips with a size of 1 mm², and then the filled SiO₂ was etched off with a BOE solution, to complete manufacturing of the UV LED.

Experiment effect: with a current of 350 mA, the wavelength was 310 nm, the brightness was 160 mW, and the forward voltage was 6.0 V.

According to the foregoing solution of the present disclosure, the diameter of the P-type nanopillar is controllable, and the density of the nanopillars is controllable. Metallic microbeads formed after annealing of a metal film are capable of guiding and catalyzing growth of nanopillars, such that the nanopillars grow vertically. Moreover, in the growth process, it is unnecessary to take out the substrate from the reaction chamber, and an in-situ growth method is used. UV light generated from the AlGaN quantum well can be effectively extracted without being absorbed, thereby greatly improving the optical power of the UV LED.

Lastly, the above preferred embodiments are only used to illustrate the technical solutions of the present disclosure but not to limit them. Although the present disclosure has been described in detail through the above preferred embodiments, a person skilled in the art should understand that various changes can be made in form and detail without departing from the scope defined by claims of the present disclosure.

What is claimed is:

1-16. (canceled)

17. An ultraviolet (UV) light-emitting diode (LED) structure, comprising: a substrate, and an undoped AlN layer, an undoped AlGaN layer, an N-type doped AlGaN layer, an AlGaN quantum well structure, and an AlGaN electron barrier layer that are sequentially grown on one surface of the substrate; and
P-type nanopillars vertically grown on the AlGaN electron barrier layer;
wherein an N-electrode and a P-electrode are evaporated on the P-type nanopillar.

18. The UV LED structure according to claim 17, wherein the P-type nanopillar is a P-type AlGaN nanopillar or a P-type GaN nanopillar.

19. The UV LED structure according to claim 17, wherein the undoped AlN layer and the undoped AlGaN layer each have a thickness of 10 to 5000 nm.

20. The UV LED structure according to claim 17, wherein an Al content in the undoped AlGaN layer is 15% to 95%.

21. The UV LED structure according to claim 19, wherein an Al content in the undoped AlGaN layer is 15% to 95%.

22. The UV LED structure according to claim 17, wherein the N-type doped AlGaN layer has a thickness of 10 to 5000 nm; and an Al content in the N-type doped AlGaN layer is 15% to 95%.

23. The UV LED structure according to claim 17, wherein the AlGaN quantum well structure is obtained by alternately growing AlGaN quantum well layers and AlGaN quantum barriers; and
the number of the grown AlGaN quantum well layers is the same as that of the grown AlGaN quantum barriers, which is 2 to 20.

24. The UV LED structure according to claim 23, wherein an Al content in the AlGaN quantum well layer and an Al content in the AlGaN quantum barrier are 15% to 85%.

25. The UV LED structure according to claim 23, wherein the AlGaN quantum well layer has a thickness of 1 to 10 nm, and the AlGaN quantum barrier has a thickness of 1 to 20 nm.

26. The UV LED structure according to claim 24, wherein the AlGaN quantum well layer has a thickness of 1 to 10 nm, and the AlGaN quantum barrier has a thickness of 1 to 20 nm.

27. The UV LED structure according to claim 17, wherein the AlGaN electron barrier layer is obtained by alternately growing AlGaN with same or different Al contents.

28. The UV LED structure according to claim 27, wherein the AlGaN electron barrier layer has a thickness of 10 to 200 nm, and the Al content in the AlGaN electron barrier layer is 15% to 95%.

29. The UV LED structure according to claim 17, wherein the P-type nanopillar has a diameter of 10 nm to 1000 nm.

30. The UV LED structure according to claim 17, wherein the N-electrode and the P-electrode are made of metal Au, Ag, Sn, Cu, Cr, Mn, Ni or Ti; or
the N-electrode and the P-electrode is made of a compound of Au, a compound of Ag, a compound of Sn, a compound of Cu, a compound of Cr, a compound of Mn, a compound of Ni, or a compound of Ti.

31. The UV LED structure according to claim 18, wherein the N-electrode and the P-electrode are made of metal Au, Ag, Sn, Cu, Cr, Mn, Ni or Ti; or
the N-electrode and the P-electrode is made of a compound of Au, a compound of Ag, a compound of Sn, a compound of Cu, a compound of Cr, a compound of Mn, a compound of Ni, or a compound of Ti.

32. The UV LED structure according to claim 19, wherein the N-electrode and the P-electrode are made of metal Au, Ag, Sn, Cu, Cr, Mn, Ni or Ti; or
the N-electrode and the P-electrode is made of a compound of Au, a compound of Ag, a compound of Sn, a compound of Cu, a compound of Cr, a compound of Mn, a compound of Ni, or a compound of Ti.

33. The UV LED structure according to claim 17, wherein an upper surface of the N-type doped AlGaN layer comprises a part covering the AlGaN quantum well structure and the AlGaN electron barrier layer and a part not covering the AlGaN quantum well structure and the AlGaN electron barrier layer;
the N-electrode is located in the part of the N-type AlGaN layer that does not cover the AlGaN quantum well structure and the AlGaN electron barrier layer; and
the P-electrode is located on an upper surface of the P-type nanopillar.

34. A method for manufacturing the UV LED structure according to claim 17, comprising:
placing a substrate in a growth reaction chamber, and sequentially growing an undoped AlN layer, an undoped AlGaN layer, and an N-type doped AlGaN layer on one surface of the substrate;
sequentially growing an AlGaN quantum well structure and an AlGaN electron barrier layer on the N-type AlGaN layer,
vertically growing P-type nanopillars on the AlGaN electron barrier layer, and
evaporating an N-electrode and a P-electrode on the P-type nanopillar.

35. The method according to claim 34, wherein after the vertically growing P-type nanopillars on the AlGaN electron barrier layer, the method further comprises: filling space between the P-type nanopillars with an insulating layer, and then removing the insulating layer after the N-electrodes and the P-electrodes are evaporated on the P-type nanopillars.

36. The method according to claim 35, wherein the growing P-type nanopillars comprises:
separately injecting a main-group III metal source to a growth reaction chamber, to form a metal film on a surface of the substrate;
annealing the metal film to form metallic microbeads; and
forming nanopillars at the metallic microbeads, and then performing P-type doping to form the P-type nanopillars.
